(19) United States
(12) Patent Application Publication
(10) Pub. No.: US 2012/0128915 A1
(43) Pub. Date: May 24, 2012

(54) GaAs Wafer And Method For Manufacturing The GaAs Wafer

(75) Inventor: Takeshi KIMURA, Hitachi-shi (JP)

(73) Assignee: HITACHI CABLE, LTD., Tokyo (JP)

(21) Appl. No.: 13/295,592

(22) Filed: Nov. 14, 2011

(30) Foreign Application Priority Data
Nov. 18, 2010 (JP) 2010-257727

(51) Int. Cl. B32B 3/02; C22C 28/00; H01L 21/20

(52) U.S. Cl. 428/64.1; 438/478; 420/579; 257/E21.09

(57) ABSTRACT

There is provided a method for manufacturing a GaAs wafer comprising: growing a GaAs single crystal by an LEC method; and fabricating a GaAs wafer by slicing the GaAs single crystal obtained by growing the GaAs single crystal, wherein in growing the GaAs single crystal, a crystal-melt interface between the GaAs single crystal and a raw material melt is formed into a convex-shape toward the raw material melt side, and a ratio T1/T2 of a length T1 from an interface between the raw material melt and a liquid encapsulant to a tip of the GaAs single crystal, and an outer diameter T2 of the GaAs single crystal, is in a range of 0.25≦T1/T2≦0.45, and the GaAs wafer obtained by fabricating the GaAs wafer has a universal hardness of 4000 N/mm² or more and 4850 N/mm² or less uniformly in a wafer surface.

The present application is based on Japanese Patent Application No. 2010-257727, filed on Nov. 18, 2010, the entire contents of which are hereby incorporated by reference.

### BACKGROUND OF THE INVENTION

1. Field of the Invention

The present invention relates to a GaAs wafer and a method for manufacturing a GaAs wafer, and particularly to a GaAs wafer capable of suppressing a generation of a slip, and the method for manufacturing the same.

2. Description of the Related Art

A compound semiconductor single crystal such as GaAs single crystal is manufactured by LEC (Liquid Encapsulated Czochralski) method, and VB (Vertical Bridgeman) method, etc. Conventionally, in a growth of a semi-insulating GaAs single crystal, it is important to form a solid-liquid interface shape during crystal growth to be a convex-shape toward a raw material melt side, to thereby prevent poly-crystallization, and various structures and growth conditions for forming a convex-shaped solid-liquid interface, are proposed (for example, patent documents 1 to 6).

Each kind of device is fabricated, using a semi-insulating GaAs wafer as a substrate, which is obtained by growing and thereafter slicing the semi-insulating GaAs single crystal. Specifically, compound semiconductor layers such as AlGaAs layer and InGaAs layer is epitaxial-grown on the GaAs wafer by a Metal Organic Chemical Vapor Deposition method (MOVPE method) and a Molecular Beam Epitaxy method (MBE method), etc., and thereafter electronic devices and light receiving devices, and light emission devices, etc., are fabricated, using a technique such as lithography and etching, etc.

Wherein, the compound semiconductor layer such as epitaxial-grown AlGaAs and InGaAs has a different composition from that of GaAs, being a base wafer, and therefore has a different lattice constant and a different thermal expansion coefficient. Therefore, as shown in FIG. 4, strain is generated in an epitaxial wafer 22 with an epitaxial layer 21 laminated on a GaAs wafer 20, and the epitaxial wafer 22 as a whole is warped in a convex-shape toward the epitaxial layer 21 in many cases.

In a device manufacturing process, the GaAs wafer is exposed to a high temperature several times. For example, in the epitaxial growth by the MOVPE method, a temperature of the GaAs wafer is raised to about 800° C. for epitaxial growth, or the GaAs wafer is also exposed to a high temperature by wafer annealing process after epitaxial growth.

### Patent Document 1:

Japanese Patent Laid Open Publication No. 1993-238870

### Patent Document 2:

Japanese Patent Laid Open Publication No. 1994-107416

### Patent Document 3:

Japanese Patent Laid Open Publication No. 2004-10467

### Patent Document 4:

Japanese Patent Laid Open Publication No. 2006-327879

### Patent Document 5:

Japanese Patent Laid Open Publication No. 2006-36604

### Patent Document 6:

Japanese Patent Laid Open Publication No. 2008-222481

As described above, the epitaxial wafer 22 on which the epitaxial layer 21 with different lattice constant is formed on the GaAs wafer 20, has at least a warp. Then, a linear line, namely a slip, along a specific crystal direction from an outer peripheral edge portion of the GaAs wafer 20, is generate on a surface of the GaAs wafer 20 as shown in FIG. 5, so as to release the warp of the GaAs wafer, namely a lattice strain, when a temperature is decreased after epitaxial growth, or when the temperature is increased/decreased during wafer annealing process performed after an epitaxial growth step. Note that designation mark 24 indicates a notch.

When a rapid temperature variation occurs in the wafer, the crystal partially moves to release the strain of the wafer, thus generating a deviation in a height of a crystal plane, and generating a level difference in a wafer surface. This is called a slip which is generated from the outer peripheral edge portion of the wafer, being an open end of the crystal, wherein the level difference is propagated to a center direction, and appears as a linear line toward the center from the outer peripheral edge portion. A device formation area is positioned on the center side of the wafer, and therefore when the slip is propagated to the device formation area, there is a problem that a failure such as a disconnection occurs in the device formed on the device formation area having the slip.

In order to suppress the generation of the slip, it is effective to reduce a temperature decreasing rate after epitaxial growth, and reduce a temperature increasing rate and a temperature decreasing rate while applying annealing process to the wafer. However, it is advantageous to increase the temperature increasing rate and the temperature decreasing rate for controlling and stabilizing the characteristics of the device in many cases. Therefore, it is difficult to reduce the temperature increasing rate and the temperature decreasing rate.

Therefore, conventionally there is provided a technique of correcting the warp after epitaxial growth and suppressing the generation of the slip, by previously forming the compound semiconductor wafer for epitaxial growth so that a center portion is low and a peripheral portion is high when a surface for growing the epitaxial layer is faced upward, in a concave shape warped concentrically, to thereby suppress the generation of slip (Japanese Patent Laid Open Publication No. 2007-214368).

However even if the wafer is formed in the concave shape as described in the conventional technique, the slip is easily generated toward the center from the outer peripheral edge portion of the wafer, by a heat treatment applied to an epitaxial wafer or an epitaxial growth, with a tendency of a larger diameter of the GaAs wafer exceeding a diameter of 150 mm. This is because it is difficult to maintain uniformity in the temperature in the wafer surface by such a larger diameter of the wafer, and even if the strain of the wafer due to warp is corrected, the strain is released by a thermal stress generated due to an uneven temperature between the center portion and the outer peripheral edge portion, and as a result, the slip toward the center from the outer edge portion of the wafer is generated. It is confirmed that the generation of the slip does not depend on a method for manufacturing GaAs single crystals such as a LEC method and a VB method, and it can be said that the problem is involved in the GaAs wafer with larger diameter exceeding the diameter of 150 mm.

### BRIEF SUMMARY OF THE INVENTION

An object of the present invention is to provide a GaAs wafer capable of suppressing a generation of a slip even in a case of a larger diameter, and a method for manufacturing A GaAs wafer.

According to an aspect of the present invention, there is provided a GaAs wafer, with a universal hardness of 4000 N/mm² or more and 4850 N/mm² or less uniformly in a wafer surface.

According to other aspect of the present invention, there is provided a method for manufacturing a GaAs wafer, comprising:

heating a crucible with a raw material and an encapsulant stored therein, and making a seed crystal brought into contact with a raw material melt covered with a liquid encapsulant in the crucible, and thereafter gradually pulling-up the seed crystal, and growing a GaAs single crystal so as to have a constant outer diameter; and

fabricating a GaAs wafer by slicing the GaAs single crystal obtained by growing the GaAs single crystal,

wherein in growing the GaAs single crystal, a crystal-melt interface between the GaAs single crystal and the raw material melt is formed into a convex-shape toward the raw material melt side, and a ratio T1/T2, being the ratio of a length T1 from an interface between the raw material melt and the liquid encapsulant to a tip of the GaAs single crystal in the raw material melt, and the outer diameter T2 of the GaAs single crystal, is in a range of 0.25≦T1/T2≦0.45, and the GaAs wafer obtained by fabricating the GaAs wafer has a universal hardness of 4000 N/mm² or more and 4850 N/mm² or less uniformly in a wafer surface.

### BRIEF DESCRIPTION OF THE DRAWINGS

FIG. 1 is a schematic block diagram of a GaAs single crystal manufacturing device used in a GaAs single crystal growth in a method for manufacturing GaAs wafers according to an embodiment of the present invention.

FIG. 2 is a sectional view showing a crystal-melt interface between a GaAs single crystal and a raw material melt, when pulling up a GaAs single crystal which is controlled to have a constant outer diameter, in growing the GaAs single crystal in the method for manufacturing the GaAs wafer according to an embodiment of the present invention.

FIG. 3 is a graph showing a relation between a convex degree of the solid-liquid interface during growth of GaAs single crystals of an example and a comparative example (ratio T1/T2 of a length T1 from an interface between a raw material melt and a liquid encapsulant to a tip end part of a GaAs crystal on the raw material melt side, and an outer diameter T2 of the GaAs crystal), and showing a universal hardness of the GaAs wafer obtained by slicing the GaAs single crystal and presence/absence of the generation of the slip after heat treatment.

FIG. 4 is a sectional view of an epitaxial wafer with an epitaxial layer formed on the GaAs wafer.

FIG. 5 is a planar view showing an example of the slip generated in the wafer after annealing process is applied to an epitaxial wafer using a conventional GaAs wafer.

### DETAILED DESCRIPTION OF THE INVENTION

Embodiments of a GaAs wafer and a method for manufacturing the GaAs wafer according to the present invention will be described hereafter.

### [GaAs Wafer]

A GaAs wafer according to an embodiment of the present invention is a hard GaAs wafer with a universal hardness on a surface (main surface) of the GaAs wafer being 4000 N/mm² or more and 4850 N/mm² or less uniformly in the wafer surface. By providing the hard GaAs wafer having the universal hardness of 4000 N/mm² or more uniformly in the wafer surface, it becomes clear that a generation of a slip failure can be suppressed even if there is an influence such as a warp of the GaAs wafer itself and an uneven temperature in the wafer surface during heat treatment, when the heat treatment is applied thereto during device manufacture processing using the GaAs wafer, for example, when the heat treatment is applied thereto for epitaxial growth and annealing process (see examples as will be described later).

The GaAs wafer having the universal hardness of 4000 N/mm² or more uniformly in the wafer surface, can be obtained by slicing the GaAs single crystal which is fabricated under a prescribed growth condition based on a LEC method as will be described later. Note that in this embodiment, an upper limit value of the universal hardness in the surface of the GaAs wafer is set to 4850 N/mm². This is because as a result of fabricating the GaAs single crystal after variously studying on the growth condition in the LEC method, the universal hardness of the GaAs wafer having highest universal hardness is 4850 N/mm².

The GaAs wafer is preferably formed by the LEC method, with its outer diameter set to 100 mm or more. Even if the GaAs wafer is formed to have a larger diameter of 100 mm or more, the generation of the slip can be suppressed, and this contributes to a mass production of the device by using the GaAs wafer with a large diameter.

Further, a surface orientation of the GaAs wafer is preferably set to the (100) plane, or a plane equivalent to the (100) plane, the (110) plane, or a plane equivalent to the (110) plane, the (111) plane or a plane equivalent to the (111) plane, from a viewpoint of characteristics of the device and fabricating the device.

The universal hardness that defines a hardness of the GaAs wafer, is an indentation hardness measured by a method for ultra-low loading hardness test. The universal hardness is obtained from the following formula (1), by pushing-in an indenter into a measured object (into the wafer surface of the GaAs wafer) while adding a load thereto.

Universal hardness=F/A(h) Formula (1)

Wherein F indicates a test load (test force) added to the measured object, and A(h) indicates a contact surface area formed by a contact of the measured object and the indenter under the test load (surface area of an indentation of the measured object generated by pushing-in the indenter into the measured object), and is calculated from an indentation depth h into the measured object of the indenter. A unit of the test load F is N (newton), and a unit of the contact surface area A(h) is mm², and a unit of the universal hardness is N/mm²(MPa).

The universal hardness can be measured by using a commercially available hardness tester, and for example, can be measured by using an ultra-micro hardness tester “Fisher Scope H-100” (by Fisher Instrument Corporation). In this ultra-micro hardness tester, the test load F loaded in a process of pushing-in a quadrangular or triangular pyramid-like indenter into the measured object, and the indentation depth h are measured continuously, then the surface area where the indenter is brought into contact with the measured object is obtained from the indentation depth when the load reaches a desired test load, to thereby calculate the universal hardness from the above-described formula (1).

Specific measurement conditions for measuring the hardness of the GaAs wafer by using the above-described ultra-micro hardness tester “Fisher scope H-100” are described as follows.
Measurement indenter: Vickers indenter
Measurement environment: Temperature 24° C., and humidity 65%
Measurement sample: GaAs wafer with a thickness of 600 μm to 750 μm
Maximum test load: 1000 mN
Load condition: Load is applied in proportion to time at a rate requiring 30 sec to reach a maximum test load.

In each sample, in a case of (100) wafer, the hardness was measured at five points of a position of 5 mm from the outer peripheral edge of the wafer, the center of the wafer, and three points for dividing a line segment between the aforementioned two points into quarters, on a straight line passing through the center of the wafer in the <001> direction. Further, the hardness was measured at four points of a position of 5 mm from the outer peripheral edge of the wafer, and three points for dividing the line segment between the position of 5 mm from the outer peripheral edge of the wafer and the center of the wafer into quarters, on the straight line passing through the center of the wafer in the <011> direction different from the <001> direction by 45° at a central angle. Namely, the universal hardness in the wafer surface of the GaAs wafer was measured at nine measurement points in total on the straight lines passing through the center of the wafer in the <001> direction and in the <011> direction. A minimum value of the universal hardness thus measured at nine points was used, to thereby define that the GaAs wafer had the universal hardness of the minimum value or more uniformly in the wafer surface.

Further, in a case of (110) wafer and (111) wafer as well, the universal hardness was measured in the same way. Namely, the universal hardness was measured at five points at equal intervals toward the center of the wafer from the position of 5 mm from the outer peripheral edge of the wafer, and was measured at four points at equal intervals toward the position of 5 mm from the outer peripheral edge from the center of the wafer by changing a center direction by 45°, and the minimum value of the nine points in total was selected to be the universal hardness of the GaAs wafer surface.

Note that the measurement point of the universal hardness is not limited to the above-described measurement point and measurement position, and may be measured at a plurality of positions suitably dispersed in the surface of the GaAs wafer.

### [A Method for Manufacturing a GaAs Wafer]

Next, an embodiment of a method for manufacturing a GaAs wafer according to the present invention will be described. The method for manufacturing a GaAs wafer according to this embodiment, includes the steps of: growing a GaAs single crystal by an LEC method; and fabricating a GaAs wafer by slicing a GaAs single crystal obtained by the growing step.

### [GaAs Single Crystal Manufacturing Apparatus]

First, a GaAs single crystal manufacturing apparatus used in the growing step of the GaAs single crystal according to this embodiment will be described. The GaAs single crystal manufacturing apparatus is an apparatus of growing the GaAs single crystal by the LEC method.

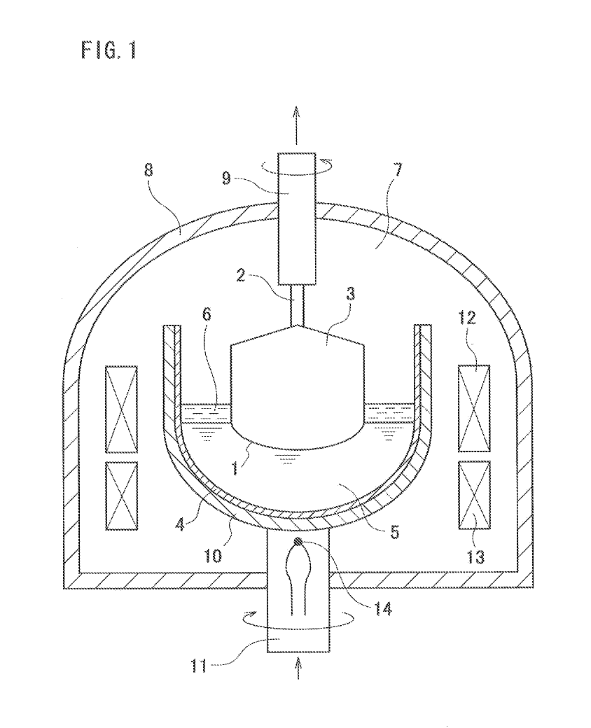

As shown in FIG. 1, the GaAs single crystal manufacturing apparatus includes: a high pressure vessel 8, being a furnace body; a pull-up shaft (upper shaft) 9 having a seed crystal 2 on a lower end for pulling-up a GaAs single crystal 3; a crucible 4, being a container for containing a raw material melt 5 and a liquid encapsulant 6; a susceptor 10 for receiving the crucible 4; a pedestal (lower shaft) 11 for supporting the susceptor 10; an upper heater 12 having a function of mainly controlling an outer diameter of the GaAs single crystal 3 by heating the crucible 4, and a lower heater 13 having a function of mainly controlling a shape of a crystal-melt interface 1.

The pull-up shaft 9 for pulling up the GaAs single crystal 3 is provided to the growth furnace composed of the high pressure vessel 8 filled with inert atmosphere gas 7, so as to pass through an upper wall of the high pressure vessel 8, and a seed crystal 2 is attached to a tip end of the pull-up shaft 9. The pedestal 11 is provided so as to pass through a bottom wall of the high pressure vessel 8, and the susceptor 10 is fixed to an upper end of the pedestal 11, so as to support the crucible 4 by the pedestal 11 via the susceptor 10. A raw material of the GaAs single crystal 3, and for example B₂O₃ as a liquid encapsulant, is contained in the crucible 4. The pedestal 11 is provided, with an axial center aligned with the pull-up shaft 9. The pedestal 11 and the pull-up shaft 9 are respectively rotated by a rotation unit (not shown), and are elevated by an elevation unit (not shown). The upper heater 12 and the lower heater 13 are provided in the high pressure vessel 8, as heating units for melting the raw material and the liquid encapsulant in the crucible. Further, a temperature controller (not shown) for controlling temperatures of the upper heater 12 and the lower heater 13 are provided, and thermocouple 14 are provided as temperature detecting units that detects the temperature of the raw material and the liquid encapsulant in the crucible 4. The upper heater 12 and the lower heater 13 are installed in a concentric arrangement with the susceptor 10 so as to surround the outer peripheral part of the susceptor 10, and the thermocouple 14 are installed in an upper part in the shaft of the pedestal 11.

### [Manufacture of the GaAs Single Crystal]

When the GaAs single crystal is manufactured, first, inside of the high pressure vessel 8 is maintained in an inert gas atmosphere. A pressure of an inert atmosphere gas 7 is set to be a pressure of preventing a dissociation of As from the raw material melt 5. Next, the upper heater 12 and the lower heater 13 are heated under temperature control by the temperature controller. By heating the crucible 4 using the upper heater 12 and the lower heater 13, first the liquid encapsulant 6 is melted, and subsequently the GaAs raw material is melted. Since a specific gravity of the raw material melt 5 of the GaAs raw material is larger than a specific gravity of the melted liquid encapsulant 6, and therefore the surface of the raw material melt 5 is covered with the liquid encapsulant 6. Thus, the dissociation of As from the raw material melt 5 is suppressed. When the crystal grows, the seed crystal 2 fixed to the tip end of the pull-up shaft 9 is brought into contact with the raw material melt 5 (for example, (100) plane of the seed crystal 2 of GaAs is brought into contact with the GaAs raw material melt 5), and in this state, the seed crystal 2 is slowly pulled p while gradually reducing the temperature of the upper heater 12 and the lower heater 13 by a feedback control of the temperature controller. Thus, the GaAs single crystal 3 grows, and the GaAs single crystal 3 is pulled up penetrating through the liquid encapsulant 6.

Further, when the raw material melt 5 in the crucible 4 is reduced, with a progress of the crystal growth, a liquid face position is necessarily lowered, and a position of the crystal growth interface relative to the upper heater 12 and the lower heater 13 is changed, thus making it difficult to efficiently heat the raw material melt 5. Therefore, the following control is carried out. Namely, a lowering amount of the liquid face is calculated from a growth amount of the GaAs single crystal 3, and the pedestal 11 is gradually elevated by the elevation unit so as to correct the lowering amount, to thereby adjust the position of the crucible 4, so that the liquid face of the raw material melt 5 is always set to a constant position with respect to a heating zone of the upper heater 12 and the lower heater 13.

The shape of the crystal-melt interface 1 between the GaAs single crystal 3 and the raw material melt 5 during manufacture of the crystal, is controlled so as to be a convex-shape toward the raw material melt 5 side. This is because a dislocation, being cause for poly-crystallization, is propagated vertically to the crystal-melt interface 1. Therefore, when the shape of the crystal-melt interface 1 is a concave surface shape toward the raw material melt 5 side, dislocations are accumulated to be the cause for the poly-crystallization. Therefore, the outer diameter of the GaAs single crystal 3 is mainly controlled by the upper heater 12, and the shape of the crystal-melt interface 1 is mainly controlled by the lower heater 13.

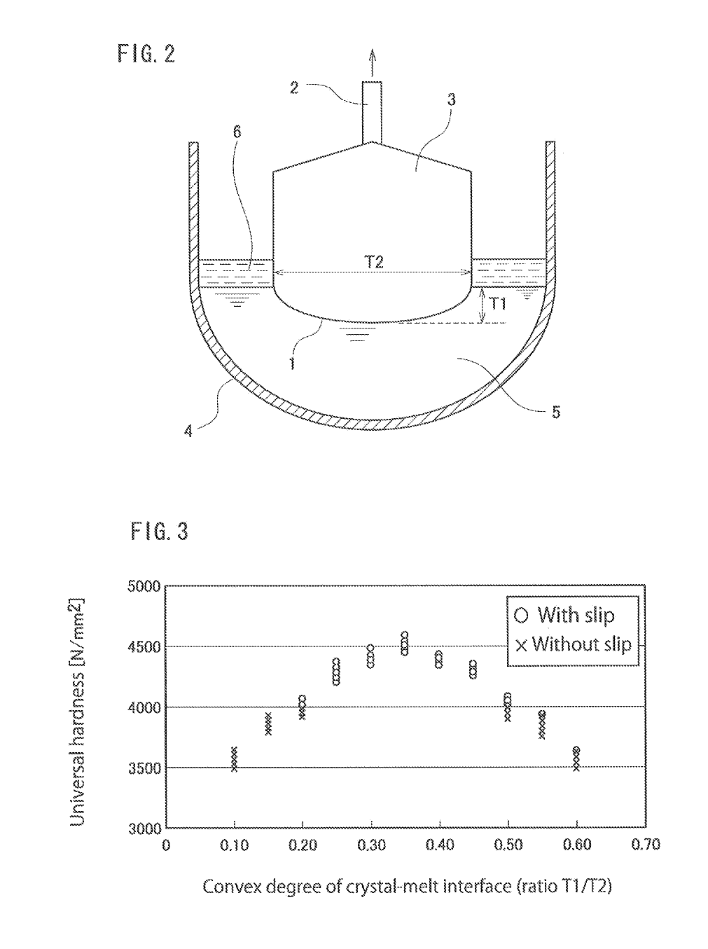

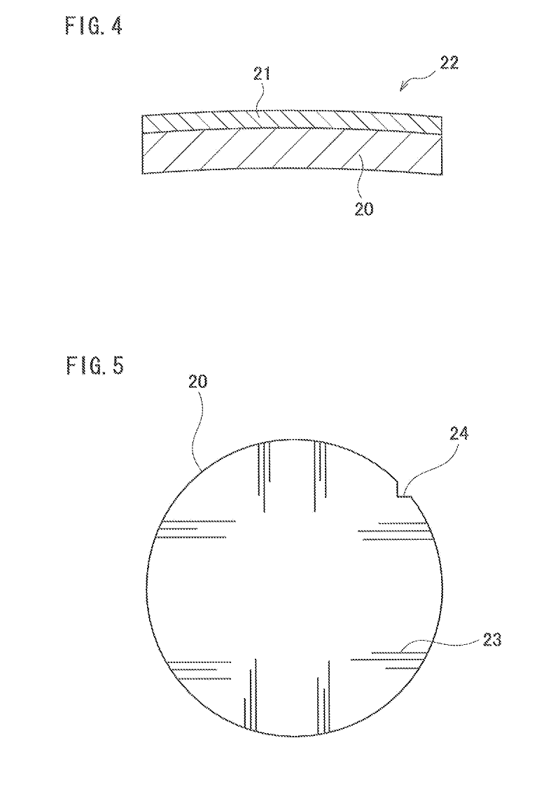

In the growth step of the GaAs single crystal by the LEC method of this embodiment, as shown in FIG. 2, the shape of the crystal-melt interface 1 between the GaAs single crystal 3 and the raw material melt 5 is formed in a convex-shape toward the raw material melt 5 side. Further, a convex degree of the crystal-melt interface 1, namely, a ratio T1/T2 of the length T1 from an interface between the raw material melt 5 and the liquid encapsulant 6, to a tip of the GaAs single crystal 3 in the raw material melt 5, and the outer diameter of the GaAs single crystal (outer diameter of a straight body part of the GaAs single crystal 3 which is pulled up by being controlled to be a constant outer diameter) T2, is set in a range of 0.25≦T1/T2≦0.45. The universal hardness of the GaAs wafer obtained by slicing the GaAs single crystal 3 grown with this range of convex degree (ratio T1/T2) can be set to 4000 N/mm² or more uniformly in the wafer surface (see FIG. 3, table 1, and table 2 of examples as will be described later), so that a device yield which is formed using the GaAs wafer as a base substrate can be maintained in a high yield without generating slip, even at a temperature decrease time after epitaxial growth, and at a temperature decrease/increase time during wafer annealing after epitaxial growth.

The GaAs single crystal 3 is sliced vertically to an axial direction, being a crystal growth direction, at equal intervals along an axial direction, after an outer periphery of its cylindrical straight body part is ground. A wire saw, an inner diameter saw, and an outer diameter saw, etc., are used for slicing the GaAs single crystal 3. Chamfering, polishing, and cleaning, etc., are further applied to a sliced GaAs wafer, to thereby obtain a GaAs wafer for a semiconductor device.

The range of the convex degree (ratio T1/T2) of the crystal-melt interface during manufacture of the GaAs single crystal is set in a range of 0.25≦T1/T2≦0.45. This is because a region where the universal hardness is less than 4000 N/mm² in the wafer surface (an entire wafer region or a partial region thereof) is generated in the GaAs wafer obtained by slicing the GaAs single crystal grown with a convex degree outside of this range. Further, the lower limit value of the universal hardness is set to 4000 N/mm². This is because in a case of the GaAs wafer with the universal hardness set to less than 4000 N/mm², slip is generated at temperature decrease time after epitaxial growth and at temperature increase/decrease time during wafer annealing after epitaxial growth. Therefore, when the GaAs single crystal is manufactured by the LEC method, it is suitable that the convex degree of the crystal-melt interface during manufacture of the single crystal in a range of 0.25≦T1/T2≦0.45. The convex degree of the crystal-melt interface is further preferably set in a range of 0.30≦T1/T2≦0.40. When the convex degree of the crystal-melt interface is set in the range of 0.25≦T1/T2≦0.45, the universal hardness of 4100 N/mm² or more can be uniformly realized in the wafer surface, and when the convex degree of the crystal-melt interface is set in a range of 0.30≦T1/T2≦0.40, the universal hardness of 4300 N/mm² or more can be realized uniformly in the wafer surface.

Consideration regarding the convex degree of the crystal-melt interface of the GaAs single crystal will be further described.

### 1. Regarding the Lower Limit of the Convex Degree of the Crystal-Melt Interface

(1) The thermal stress added to the GaAs single crystal is increased, as the convex degree is increased.
(2) When the thermal stress exceeds a critical level of stress relaxation (for example, a critical resolved shear stress), relaxation of the stress due to dislocation to the GaAs single crystal is generated.
(3) As the convex degree is reduced, the thermal stress added to the GaAs single crystal is reduced, and the generation of the dislocation is also reduced.
(4) When the convex degree is less than 0.25, it can be considered that the stress relaxation due to dislocation is insufficient, and a residual strain value exceeds 3.0×10⁻⁵, and the universal hardness is less than 4000 N/mm².

### 2. Regarding the Upper Limit of the Convex Degree of the Crystal-Melt Interface

(1) As the convex degree is increased, the generation of the dislocation is increased.
(2) When the convex degree exceeds 0.45, it can be considered that the dislocation density exceeds 10⁵/cm², and the universal hardness is 4000 N/mm² or less.

Explanation has been given for a relation between the convex degree and the dislocation, thermal stress, and strain, as described above. Other reason is also examined.

Namely, as the convex degree is increased, a difference is generated in solidification times in the wafer plane (in the same plane of the wafer). Thus, it can be considered that there is a possibility that the difference is generated in the hardness in the wafer surface. Specifically, intake of carbon into the GaAs crystal is different depending on GaAs solidification times. Namely, a difference is generated in the intake of carbon in the wafer surface (the difference in the wafer surface of carbon concentration is increased). When the convex degree exceeds 0.45, the difference in the wafer surface of the carbon concentration {(carbon concentration of a wafer outer peripheral part−carbon concentration of a wafer center part)/carbon concentration of a wafer center part} exceeds 30% and the universal hardness is less than 4000 N/mm².

Note that in the aforementioned embodiment, the GaAs single crystal is fabricated using the LEC method. However, if a hard GaAs wafer with universal hardness of 4000 N/mm² or more can be obtained uniformly in the wafer surface, of course the GaAs single crystal may be fabricated using not only the LEC method but also the VB method, etc.

### EXAMPLES

Examples of the present invention will be described next.

### Example 1

In example 1 (examples 1-1 to 1-5), the GaAs single crystal was grown using a GaAs single crystal manufacturing apparatus of the embodiment shown in FIG. 1, and the GaAs single crystal was sliced to fabricate a (100) just GaAs wafer (a (100) just substrate) having a diameter of 50 mm and an off-angle of 0°.

### Example 1-1

GaAs polycrystal 40,000 g was put in the crucible 4 made of pBN, and boron trioxide (B₂O₃) 2,500 g was put therein as the liquid encapsulant, which were then stored in a high pressure vessel 8 and the vessel 8 was filled with an inert atmosphere gas 7 so that, a pressure in the high pressure vessel 8 set to 9.0 kgf/cm². Nitrogen gas was used as the inert gas, and a concentration of the nitrogen gas in the atmosphere gas 7 was set to 97 volume %. After filling of the inert atmosphere gas 7, the boron trioxide and the GaAs polycrystal were melted by heating the crucible 4 using the upper heater 12 and the lower heater 13. Thereafter, seeding was carried out by adjusting a temperature, and the GaAs single crystal having a diameter of 150 mm was grown by controlling the temperature by the upper heater 12 and the lower heater 13 so that the convex degree of the crystal-melt interface was 0.35, thus growing the GaAs single crystal having a full length of 300 mm.

The concentration of the nitrogen gas in the atmosphere gas 7 is preferably controlled in a range of 95 volume % to 99 volume %, and the pressure in the high pressure vessel 8 is preferably controlled in a range of 7.0 kgf/cm² to 9.0 kgf/cm². Further, CO gas and CO₂ gas are preferably mixed into the atmosphere gas with a concentration of 0.1 volume % or more and 5 volume % or less, to thereby control the intake of carbon into the GaAs single crystal. Note that in the control of the concentration of the atmosphere gas in the high pressure vessel 8, the concentration of the gas in the high pressure vessel 8 was measured not directly but indirectly by measuring a flow rate of the gas supplied to the high pressure vessel 8 and estimating the obtained value. Namely, the flow rate of the gas supplied to the high pressure vessel 8 was measured by a mass flow meter and the concentration of the gas in the high pressure vessel 8 was calculated from the measured flow rate of the gas, and based on a calculation result of the concentration of the gas, the flow rate of the gas was adjusted by the mass flow meter, to thereby control the concentration of the atmosphere gas in the high pressure vessel 8.

By growing the GaAs single crystal under the growth condition of the concentration of the nitrogen gas, the surface of the growing GaAs single crystal is covered with a nitride film (GaNAs film and GaN film), thus making it possible to suppress Ga drop on the surface of a straight body part of the GaAs single crystal by being heated by a heater. It can be considered that a GaNAs film is initially formed as the nitride film, and thereafter As dissociates from a part of the GaNAs film to thereby form the GaN film. The nitride film with a thickness of 2 to 10 nm was formed on the surface of the grown GaAs single crystal by growing the GaAs single crystal under the aforementioned condition of nitrogen gas concentration.

Further, by mixing the carbon-containing gas (CO gas and CO₂ gas) into the atmosphere gas in the aforementioned concentration range, the following effects can be exhibited. Namely, the variation of the universal hardness in the surface of the GaAs wafer can be suppressed within a prescribed range, and the variation of electric characteristics of the GaAs wafer itself can also be suppressed.

Regarding the (100) just GaAs wafers obtained by fabricating five GaAs single crystals under the aforementioned growth condition and slicing the GaAs single crystals, the universal hardness was 4450 N/mm² or more in all wafers. In the GaAs wafer having high hardness fabricated by example 1-1, the GaAs wafer with a maximum value of the universal hardness being 4800 N/mm², and the universal hardness in the wafer surface being 4785 N/mm² or more, was obtained at measuring points (the above-described measuring points) in the wafer surface. Further, a specific resistance of all GaAs wafers obtained by the example 1-1 was 1×10⁸ Ω·cm or more.

Several kinds of epitaxial layers including an AlGaAs layer with a thickness of 1 μm in total was grown on these GaAs wafers by a MOVPE apparatus. Thereafter, the GaAs wafers having the epitaxial layer were arranged in a wafer annealing furnace, and a temperature was increased from a room temperature to 850° C. at a temperature increasing rate of 600° C./h in a hydrogen gas atmosphere, and subsequently the temperature was decreased from 850° C. to the room temperature at a temperature decreasing rate of 600° C./h.

Presence/absence of generation of slip in the GaAs wafer to which wafer annealing was applied, was observed visually. The generation of slip was not observed (0 in 20 GaAs wafers).

Next, explanation will be given for examples 1-2 to 1-5 and comparative example 1 (comparative examples 1-1 to 1-6) wherein (100) just GaAs wafers with a diameter of 150 mm were fabricated under the same condition, excluding a point that the convex degree of the crystal-melt interface during growth of the GaAs single crystal was changed in the embodiment 1-1 (convex degree 0.35 in the example 1-1).

### Example 1-2

In the example 1-2, five GaAs single crystals were fabricated by growing them using the upper heater 12 and the lower heater 13 so that the convex degree of the crystal-melt interface was set to 0.30. The universal hardness of the (100) just GaAs wafers fabricated by slicing the obtained GaAs single crystals, was 4350 N/mm² or more in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. The presence/absence of the generation of slip in the GaAs wafers after wafer annealing processing was observed visually. The generation of slip was not observed (0 in 20 GaAs wafers).

### Example 1-3

In the example 1-3, five GaAs single crystals were fabricated by growing them using the upper heater 12 and the lower heater 13 so that the convex degree of the crystal-melt interface was set to 0.25. The universal hardness of the (100) just GaAs wafers fabricated by slicing the obtained GaAs single crystals, was 4200 N/mm² or more in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. The presence/absence of the generation of slip in the GaAs wafer after wafer annealing processing was observed visually. The generation of slip was not observed (0 in 20 GaAs wafers).

### Example 1-4

In the example 1-4, five GaAs single crystals were fabricated by growing them using the upper heater 12 and the lower heater 13 so that the convex degree of the crystal-melt interface was set to 0.40. The universal hardness of the (100) just GaAs wafers fabricated by slicing the obtained GaAs single crystals, was 4350 N/mm² or more in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. The presence/absence of the generation of slip in the GaAs wafers after wafer annealing processing was observed visually. The generation of slip was not observed (0 in 20 GaAs wafers).

### Example 1-5

In the example 1-5, five GaAs single crystals were fabricated by growing them using the upper heater 12 and the lower heater 13 so that the convex degree of the crystal-melt interface was set to 0.45. The universal hardness of the (100) just GaAs wafers fabricated by slicing the obtained GaAs single crystals, was 4250 N/mm² or more in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. The presence/absence of the generation of slip in the GaAs wafers after wafer annealing processing was observed visually. The generation of slip was not observed (0 in 20 GaAs wafers).

### Comparative Example 1

### Comparative Example 1-1

In the comparative example 1-1, five GaAs single crystals were fabricated by growing them using the upper heater 12 and the lower heater 13 so that the convex degree of the crystal-melt interface was set to 0.20. The universal hardness of the (100) just GaAs wafers manufactured by slicing the obtained GaAs single crystals, was in a range of 3900 to 4100 N/mm² at measuring points in the wafer surface, and it was found that one or more measuring points where the universal hardness was less than 4000 N/mm² existed in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. When the presence/absence of the generation of the slip in the GaAs wafers after wafer annealing processing was observed visually, the generation of slip was recognized (8 in 20 GaAs wafers). In the wafers where the slip was generated, a plurality of measuring points existed where the universal hardness was less than 4000 N/mm².

### Comparative Example 1-2

In the comparative example 1-2, five GaAs single crystals were fabricated by growing them using the upper heater 12 and the lower heater 13 so that the convex degree of the crystal-melt interface was set to 0.15. The universal hardness of the (100) just GaAs wafers fabricated by slicing the obtained GaAs single crystals, was less than 3950 N/mm² in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. When the presence/absence of the generation of the slip in the GaAs wafers after wafer annealing processing was observed visually, the generation of slip was recognized in many wafers (16 in 20 GaAs wafers).

### Comparative Example 1-3

In the comparative example 1-3, five GaAs single crystals were fabricated by growing them using the upper heater 12 and the lower heater 13 so that the convex degree of the crystal-melt interface was set to 0.10. The universal hardness of the (100) just GaAs wafers fabricated by slicing the obtained GaAs single crystals, was less than 3700 N/mm² in all wafers. Several kinds of epitaxial layers including the AlGaAs layer with a thickness of 1 μm in total were epitaxial-grown on these

GaAs wafers by the MOVPE apparatus. Thereafter, the wafer annealing processing was applied thereto under the same condition as the condition of the example 1-1. The presence/absence of the generation of slip in the GaAs wafer after wafer annealing processing was observed visually. The generation of slip was observed in most of the wafers (18 in 20 GaAs wafers).

### Comparative Example 1-4

In the comparative example 1-4, five GaAs single crystals were fabricated by growing them using the upper heater 12 and the lower heater 13 so that the convex degree of the crystal-melt interface was set to 0.50. The universal hardness of the (100) just GaAs wafers fabricated by slicing the obtained GaAs single crystals, was in a range of 3900 to 4100 N/mm² at measuring points in the wafer surface, and it was found that one or more measuring points existed where the universal hardness was less than 4000 N/mm² in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. When the presence/absence of the generation of slip in the GaAs wafers after wafer annealing was observed visually, it was found that the generation of slip was recognized (6 in 20 GaAs wafers). In the wafers where the slip was generated, a plurality of measuring points exited where the universal hardness was less than 4000 N/mm².

### Comparative Example 1-5

In the comparative example 1-5, five GaAs single crystals were fabricated by growing them using the upper heater 12 and the lower heater 13 so that the convex degree of the crystal-melt interface was set to 0.55. The universal hardness of the (100) just GaAs wafers fabricated by slicing the obtained GaAs single crystals, was less than 3950 N/mm² in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. When the presence/absence of the generation of slip in the GaAs wafers after Wafer annealing processing was observed visually, the generation of slip was recognized in many wafers (10 in 20 GaAs wafers).

### Comparative Example 1-6

In the comparative example 1-6, five GaAs single crystals were fabricated by growing them using the upper heater 12 and the lower heater 13 so that the convex degree of the crystal-melt interface was set to 0.60. The universal hardness of the (100) just GaAs wafers fabricated by slicing the obtained GaAs single crystals, was less than 3650 N/mm² in all wafers. Several kinds of epitaxial layers including the AlGaAs layer with a thickness of 1 μm in total were epitaxial-grown on these GaAs wafers by the MOVPE apparatus. Thereafter, the wafer annealing processing was applied thereto under the same condition as the condition of the example 1-1. When the presence/absence of the generation of slip in the GaAs wafers after wafer annealing processing was observed visually, the generation of slip was recognized in many wafers (14 in 20 GaAs wafers).

Results of trial products of the example 1 and the comparative example 1 as described above are shown in FIG. 3. From the above-described results of trial products, it was confirmed that the convex degree of the crystal-melt interface during fabrication of the single crystal is preferably defined in a range of 0.25≦T1/T2≦0.45.

### Example 2

In the example 1, explanation was given for a case that the GaAs single crystal with a large diameter of about 150 mm was manufactured by the LEC method, and the (100) just GaAs wafer with a diameter of 150 mm was fabricated by slicing the GaAs single crystal. However, the manufacturing method of the present invention can also be applied to a manufacture of the GaAs single crystal having a diameter of less than 150 mm. In the example 2, the (100) just GaAs wafers having an off-angle of 0° were fabricated, with a diameter of 100 mm and a diameter of 125 mm. In the example 2 as well, by defining the convex degree of the crystal-melt interface during manufacture of the single crystal in the range of 0.25≦T1/T2≦0.45, similarly to the example 1, the hard GaAs wafer could be obtained, with universal hardness of 4000 N/mm² or more uniformly in the wafer surface. In the heat treatment using the hard GaAs wafer during a device manufacture process as well, it was confirmed that the GaAs wafer capable of ignoring problems such as a warped shape of a wafer itself and an uneven temperature in the wafer surface during heat treatment could be realized, namely the GaAs wafer without generation of a slip failure could be realized. Results of the example 2 (example 2-1 to example 2-4) and comparative example 2 (comparative example 2-1 to comparative example 2-4) are shown in table 1. Note that in all wafers of the comparative example 2-1 to the comparative example 2-4 shown in table 1, one or more measuring points existed, where the universal hardness is at least less than 4000 N/mm².

TABLE 1

| | Universal hardness | Generation rate of slip |
|---|---|---|
| | (N/mm²) | (%) |
| Example 2-1 | 4150~4300 | 0 |
| (outer diameter: 100 mm, | | (0 in 20 GaAs wafers) |
| convex degree: 0.25) | | |
| Example 2-2 | 4200~4300 | 0 |
| (outer diameter: 100 mm, | | (0 in 20 GaAs wafers) |
| convex degree: 0.45) | | |
| Example 2-3 | 4150~4250 | 0 |
| (outer diameter: 125 mm, | | (0 in 20 GaAs wafers) |
| convex degree: 0.25) | | |
| Example 2-4 | 4200~4350 | 0 |
| (outer diameter: 125 mm, | | (0 in 20 GaAs wafers) |
| convex degree: 0.45) | | |
| Comparative Example 2-1 | 3900~4050 | 30 |
| (outer diameter: 100 mm, | | (6 in 20 GaAs wafers) |
| convex degree: 0.20) | | |
| Comparative Example 2-2 | 3850~4050 | 35 |
| (outer diameter: 100 mm, | | (7 in 20 GaAs wafers) |
| convex degree: 0.50) | | |
| Comparative Example 2-3 | 3900~4100 | 35 |
| (outer diameter: 125 mm, | | (7 in 20 GaAs wafers) |
| convex degree: 0.20) | | |
| Comparative Example 2-4 | 3950~4100 | 25 |
| (outer diameter: 125 mm, | | (5 in 20 GaAs wafers) |
| convex degree: 0.50) | | |

### Example 3

Further, in the example 1, explanation is given for a case of the GaAs wafer with slice processing applied to the (100) plane. However, the manufacturing method of the present invention can also be applied to the GaAs wafer having other surface orientations such as the (110) plane or the (111) plane. In the example 3, (110) GaAs wafer and (111) GaAs wafer were fabricated, with a diameter of 150 mm. In the example 3 as well, by defining the convex degree of the crystal-melt interface during manufacture of the single crystal in the range of 0.25≦T1/T2≦0.45, the hard GaAs wafer with universal hardness of 4000 N/mm² or more could be obtained uniformly in the wafer surface. Further, in a case of the hard GaAs wafer with universal hardness being 4000 N/mm² or more uniformly in the wafer plane, it was confirmed that problems such as warped shape of the wafer itself and an uneven temperature in the wafer surface during heat treatment could be ignored, namely the GaAs wafer without generation of the slip failure could be realized in the heat treatment during the device manufacture process using the GaAs wafer. Results of the example 3 (example 3-1 to example 3-4) and comparative example 3 (comparative example 3-1 to comparative example 3-4) are shown in table 2. Note that in all wafers of the comparative example 3-1 to the comparative example 3-4 shown in table 2, one or more measuring points existed, where the universal hardness was at least less than 4000 N/mm².

TABLE 2

| | Universal hardness | Generation rate of slip |
|---|---|---|
| | (N/mm²) | (%) |
| Example 3-1 | 4100~4300 | 0 |
| (Surface orientation: (110), | | (0 in 20 GaAs wafers) |
| Convex degree: 0.25) | | |
| Example 3-2 | 4150~4350 | 0 |
| (Surface orientation: (110), | | (0 in 20 GaAs wafers) |
| Convex degree: 0.45) | | |
| Example 3-3 | 4150~4300 | 0 |
| (Surface orientation: (111), | | (0 in 20 GaAs wafers) |
| Convex degree: 0.25) | | |
| Example 3-4 | 4100~4250 | 0 |
| (Surface orientation: (111), | | (0 in 20 GaAs wafers) |
| Convex degree: 0.45) | | |
| Comparative Example 3-1 | 3950~4100 | 35 |
| (Surface orientation: (110), | | (7 in 20 GaAs wafers) |
| Convex degree: 0.20) | | |
| Comparative Example 3-2 | 3900~4050 | 30 |
| (Surface orientation: (110), | | (6 in 20 GaAs wafers) |
| Convex degree: 0.50) | | |
| Comparative Example 3-3 | 3950~4100 | 25 |
| (Surface orientation: (111), | | (5 in 20 GaAs wafers) |
| Convex degree: 0.20) | | |
| Comparative Example 3-4 | 3950~4050 | 30 |
| (Surface orientation: (111), | | (6 in 20 GaAs wafers) |
| Convex degree: 0.50) | | |

### Example 4

The GaAs wafer of the examples 1 and 2 is the (100) just substrate having an off-angle of 0° with respect to the (100) plane. However, in the example 4 (example 4-1 to example 4-3), the GaAs single crystal was grown under a condition similar to the condition of the example 1 and the GaAs single crystal thus obtained was sliced, to thereby fabricate the GaAs wafer (off substrate) having a prescribed off-angle in a prescribed off-direction with respect to the (100) plane.

### Example 4-1

The GaAs wafer having an off-angle of 0.5° in an off-direction of <0-11> with respect to the (100) plane, was fabricated. In this example 4-1 as well, the hard GaAs wafer with universal hardness of 4000 N/mm² or more uniformly in the wafer surface could be obtained by defining the convex degree of the crystal-melt interface during manufacture of the single crystal in the range of 0.25≦T1/T2≦0.45. Further, the manufacture of a device including the heat treatment similar to the heat treatment of the example 1 was performed using the hard GaAs wafer thus obtained. The generation of the slip was not recognized after the heat treatment.

### Example 4-2

The GaAs wafer having an off-angle of 0.4° in an off-direction of <110> with respect to the (100) plane, was fabricated. In this example 4-2 as well, the hard GaAs wafer with universal hardness of 4000 N/mm² or more uniformly in the wafer surface could be obtained by defining the convex degree of the crystal-melt interface during manufacture of the single crystal in the range of 0.25≦T1/T2≦0.45. Further, the manufacture of a device including the heat treatment similar to the heat treatment of the example 1 was performed using the hard GaAs wafer thus obtained. The generation of the slip was not recognized.

### Example 4-3

The GaAs wafer having an off-angle of 1° to 15° in an off-direction of <011> or an off-direction of <0-1-1> with respect to the (100) plane, was fabricated. In this example 4-3 as well, the hard GaAs wafer with universal hardness of 4000 N/mm² or more uniformly in the wafer surface could be obtained by defining the convex degree of the crystal-melt interface during manufacture of the single crystal in the range of 0.25≦T1/T2≦0.45. Further, the manufacture of a device including the heat treatment similar to the heat treatment of the example 1 was performed using the hard GaAs wafer thus obtained. The generation of the slip was not recognized.

Note that in the manufacture of the GaAs wafer with a desired surface orientation, the GaAs single crystal may also be grown in such manner that a surface orientation of a seed crystal brought into contact with the GaAs raw material melt is aligned to the surface orientation of the GaAs wafer desired to be fabricated. However, the GaAs wafer with a desired surface orientation and off-angle may also be obtained by making the (100) plane of the seed crystal brought into contact with the GaAs raw material melt and adjusting a slicing direction and a polishing direction with respect to a pulled-up GaAs single crystal.

What is claimed is:

1. A GaAs wafer, wherein universal hardness is 4000 N/mm² or more and 4850 N/mm² or less uniformly in a wafer surface.

2. The GaAs wafer according to claim 1, wherein the GaAs wafer is formed by an LEC method, and an outer diameter of the GaAs wafer is 100 mm or more.

3. The GaAs wafer according to claim 1, wherein a surface orientation of the GaAs wafer is the (100) plane, a plane equivalent to the (100) plane, the (110) plane, a plane equivalent to the (110) plane, the (111) plane, or a plane equivalent to the (111) plane.

4. A method for manufacturing a GaAs wafer, comprising:
heating a crucible with a raw material and an encapsulant stored therein, and making a seed crystal brought into contact with a raw material melt covered with a liquid encapsulant in the crucible, and thereafter gradually pulling-up the seed crystal, and growing a GaAs single crystal so as to have a constant outer diameter; and
fabricating a GaAs wafer by slicing the GaAs single crystal obtained by growing the GaAs single crystal,
wherein in growing the GaAs single crystal, a crystal-melt interface between the GaAS single crystal and the raw material melt is formed into a convex-shape toward the raw material melt side, and a ratio T1/T2, being the ratio of a length T1 from an interface between the raw material melt and the liquid encapsulant to a tip of the GaAs single crystal in the raw material melt, and the outer diameter T2 of the GaAs single crystal, is in a range of 0.25≦T1/T2≦0.45, and the GaAs wafer obtained by fabricating the GaAs wafer has a universal hardness of 4000 N/mm² or more and 4850 N/mm² or less uniformly in a wafer surface.
